(19) United States
(12) Patent Application Publication
(10) Pub. No.: US 2026/0018505 A1
(43) Pub. Date: Jan. 15, 2026

(54) FAN-OUT WAFER LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/254,003

(22) Filed: Jun. 30, 2025

(30) Foreign Application Priority Data
Jul. 12, 2024 (TW) 113126321

(51) Int. Cl. H01L 23/498; H01L 21/48; H01L 23/00; H01L 23/15; H01L 23/66; H05K 1/18

(52) U.S. Cl. CPC H01L 23/49838; H01L 21/4867; H01L 23/15; H01L 23/49811; H01L 23/49866; H01L 23/66; H01L 24/11; H01L 24/13; H01L 24/16; H01L 24/32; H01L 24/73; H01L 2223/6677; H01L 2224/11602; H01L 2224/13139; H01L 2224/13147; H01L 2224/16225; H01L 2224/32225; H01L 2224/32245; H01L 2224/73253; H05K 1/181

(57) ABSTRACT

A fan-out wafer level packaging (FOWLP) unit which includes a substrate, a first dielectric layer, at least one antenna, at least one die, a second dielectric layer, at least one conductive pillar, a plurality of first conductive circuits, a third dielectric layer, a plurality of second conductive circuits, and an outer protective layer is provided. The first conductive circuits and the second conductive circuits are produced by filling a metal paste into slots and grinding the metal paste. The die is electrically connected with the antenna. The die is electrically connected to the outside through bonding pads around a chip area on a second surface of the die. Thereby the FOWLP unit is formed and problems of the FOWLP module or technology available now generated during manufacturing of the respective conductive circuits including higher manufacturing cost and less environmental benefit can be solved.

### CROSS-REFERENCE TO RELATED APPLICATIONS

This non-provisional application claims priority under 35 U.S.C. § 119(a) on Patent Application No(s). 113126321 filed in Taiwan, R.O.C. on Jul. 12, 2024, the entire contents of which are hereby incorporated by reference.

### BACKGROUND OF THE INVENTION

The present invention relates to a packaging unit, especially to a fan-out wafer level packaging (FOWLP) unit.

Packaging technology with features of compact design, high efficiency, and high reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly.

Moreover, wireless communication technology has been widely applied to electronic products for receiving or transmitting various kinds of wireless signals. In order to meet requirements of light weight and small size, how to arrange antennas in the FOWLP unit is an important issue which needs to be addressed.

### SUMMARY OF THE INVENTION

Therefore, it is a primary object of the present invention to provide a FOWLP unit which includes a substrate, a first dielectric layer, at least one antenna, at least one die, a second dielectric layer, at least one conductive pillar, a plurality of first conductive circuits, a third dielectric layer, a plurality of second conductive circuits, and an outer protective layer. The first conductive circuits and the second conductive circuits are produced by filling a metal paste into slots and grinding the metal paste. The die is electrically connected with the antenna. The die is electrically connected with the outside through bonding pads around a chip area on a second surface of the die. Thereby the FOWLP unit is formed and problems of the FOWLP module or technology available now generated during manufacturing of the respective conductive circuits including higher manufacturing cost and less environmental benefit can be solved.

In order to achieve the above object, a FOWLP unit according to the present invention includes a substrate, a first dielectric layer, at least one antenna, at least one die, a second dielectric layer, at least one conductive pillar, a plurality of first conductive circuits, a third dielectric layer, a plurality of second conductive circuits, and an outer protective layer. The first dielectric layer is arranged at the substrate and provided with at least one first slot extending in a horizontal direction. The antenna is mounted in the first slot. The die is cut from a wafer and provided with a first surface and a second surface opposite to each other. The first surface of the die is fixed on the first dielectric layer and the antenna while the second surface of the die is provided with a plurality of die pads. A range perpendicular to the second surface of the die is defined as a chip area. The second dielectric layer is disposed over the first dielectric layer, the antenna, and the second surface of the die. The second dielectric layer is provided with a plurality of second slots extending in a horizontal direction and at least one insertion hole penetrating the second dielectric layer. The respective die pads of the die are exposed through the respective second slots and the antenna is exposed through the corresponding insertion hole. The conductive pillar is formed in the insertion hole and electrically connected with the antenna. The respective first conductive circuits are formed by a metal paste filled in the respective second slots and electrically connected with the die pads of the die. The third dielectric layer is arranged over the second dielectric layer and provided with a plurality of third slots extending in a horizontal direction. The respective third slots are communicating with the respective second slots. The respective second conductive circuits are formed by a metal paste filled in the respective third slots and electrically connected with both the respective first conductive circuits and the conductive pillar. The outer protective layer is mounted over the third dielectric layer and provided with a plurality of openings. At least one of the openings is located around the chip area on the second surface of the die. The respective second conductive circuits are exposed through the respective openings to form a bonding pad in each of the openings. The die is electrically connected to the antenna through the first conductive circuits and the conductive pillar in turn. The die is electrically connected to the outside through the die pads, the first conductive circuits, the second conductive circuits, and the bonding pads located around the chip area on the second surface of the die in turn. Thereby the FOWLP unit is formed. A method of manufacturing the FOWLP unit includes the following steps. Step S1: providing a substrate. Step S2: disposing a first dielectric layer on the substrate and forming a plurality of first slots on the first dielectric layer. Step S3: forming an antenna in each of the first slots. Step S4: arranging a plurality of dies cut from at least one wafer at the first dielectric layer and the antenna with an interval between the two adjacent dies. The die is provided with a first surface and a second surface opposite to the first surface. The first surface of the die is fixed on the first dielectric layer and the antenna while the second surface of the die is provided with a plurality of die pads. A range perpendicular to the second surface of the die is defined as a chip area. Step S5: producing a plurality of first conductive circuits on the second surface of the die by filling a metal paste into slots and grinding the metal paste. First paving a second dielectric layer over the first dielectric layer, the antenna, and the die. Then forming a plurality of second slots extending in a horizontal direction and a plurality of insertion holes on the second dielectric layer and allowing the die pads of the die and the respective antennas respectively to expose through the second slots and the insertion holes. Next forming a conductive pillar in each of the insertion holes, filling a metal paste into the respective second slots, and allowing a level of the metal paste to be higher than a surface of the second dielectric layer. Lastly, grinding the metal paste with the level higher than the surface of the second dielectric layer to make a surface of the metal paste flush with the surface of the second dielectric layer and form a plurality of the first conductive circuits. Step S6: producing a plurality of second conductive circuits on the second dielectric layer and the first conductive circuits by filling a metal paste into slots and grinding the metal paste. First paving a third dielectric layer over the second dielectric layer and the first conductive circuits. Then forming a plurality of third slots extending in a horizontal direction on the third dielectric layer and allowing the first conductive circuits to expose through the third slots. Next filling a metal paste into the third slots and allowing a level of the metal paste to be higher than a surface of the third dielectric layer. Lastly, grinding the metal paste with the level higher than the surface of the third dielectric layer to make a surface of the metal paste flush with the surface of the third dielectric layer and form a plurality of the second conductive circuits. Step S7: covering the third dielectric layer with an outer protective layer. Step S8: forming a plurality of openings on the outer protective layer and allowing at least one of the openings to be located around the chip area on the second surface of the die so that the respective second conductive circuits are exposed through the respective openings to form a bonding pad in each of the openings. Step S9: performing cutting to form a plurality of the FOWLP units.

Preferably, the substrate includes silicon (Si) substrate, glass substrate, and ceramic substrate.

Preferably, the metal paste which forms the first conductive circuits includes silver paste, nano-scale silver paste, copper paste, and nano-scale copper paste.

Preferably, the metal paste which forms the second conductive circuits includes silver paste, nano-scale silver paste, copper paste, and nano-scale copper paste.

Preferably, the first surface of the die is arranged at the first dielectric layer and the antenna by a die attach film (DAF).

Preferably, each of the openings is provided with a solder ball which is electrically connected with the bonding pad inside the opening.

Preferably, the FOWLP unit is electrically connected and mounted to a printed circuit board (PCB) by the solder balls.

### BRIEF DESCRIPTION OF THE DRAWINGS

FIG. 1 is a side sectional view of an embodiment of a FOWLP unit according to the present invention;

FIG. 2 is a schematic drawing showing a side section of a substrate according to the present invention;

FIG. 3 is a side sectional view showing an antenna disposed on a first dielectric layer on a substrate of the embodiment in FIG. 2 according to the present invention;

FIG. 4 is a side sectional view showing a die arranged at the first dielectric layer of the embodiment in FIG. 3 according to the present invention;

FIG. 5 is a side sectional view showing a second dielectric layer disposed on the die of the embodiment in FIG. 4 according to the present invention;

FIG. 6 is a side sectional view showing a conductive pillar mounted to the second dielectric layer of the embodiment in FIG. 4 according to the present invention;

FIG. 7 is a side sectional view showing a metal paste filled into second slots of the embodiment in FIG. 6 according to the present invention;

FIG. 8 is a side sectional view showing grinding of the metal paste in the second slots of the embodiment in FIG. 7 to form first conductive circuits according to the present invention;

FIG. 9 is a side sectional view showing a third dielectric layer disposed over the second dielectric layer of the embodiment in FIG. 8 according to the present invention;

FIG. 10 is a side sectional view showing a metal paste filled into third slots of the embodiment in FIG. 9 according to the present invention;

FIG. 11 is a side sectional view showing grinding of the metal paste in the third slots of the embodiment in FIG. 10 to form second conductive circuits according to the present invention;

FIG. 12 is a side sectional view showing an outer protective layer disposed over the third dielectric layer of the embodiment in FIG. 11 according to the present invention;

FIG. 13 is a side sectional view showing solder balls mounted in openings of the embodiment in FIG. 12 according to the present invention.

### DETAILED DESCRIPTION OF THE PREFFERED EMBODIMENT

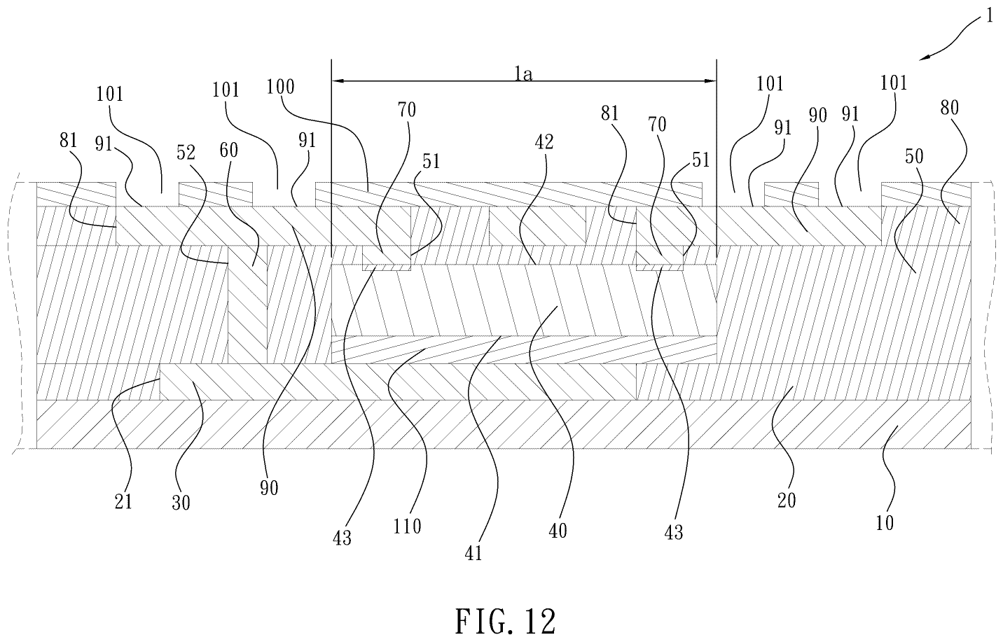

Refer to FIG. 12, a fan-out wafer-level packaging (FOWLP) unit 1 according to the present invention includes a substrate 10, a first dielectric layer 20, at least one antenna 30, at least one die 40, a second dielectric layer 50, at least one conductive pillar 60, a plurality of first conductive circuits 70, a third dielectric layer 80, a plurality of second conductive circuits 90, and an outer protective layer 100.

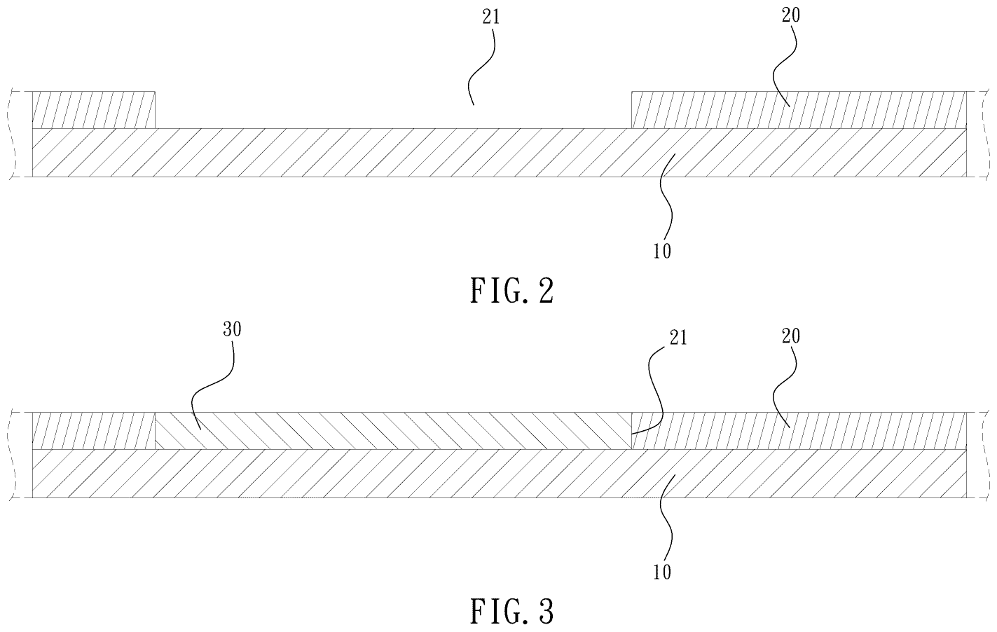

The first dielectric layer 20 is arranged at the substrate 10 and provided with at least one first slot 21 extending in a horizontal direction, as shown in FIG. 2.

The antenna 30 is mounted in the first slot 21, as shown in FIG. 3. That means the antenna 30 is embedded in the FOWLP unit 1 and formed by a patterned circuit layer in the first slot 21. Since the patterned circuit layer of the antenna is the technique available now, no more detailed description is provided.

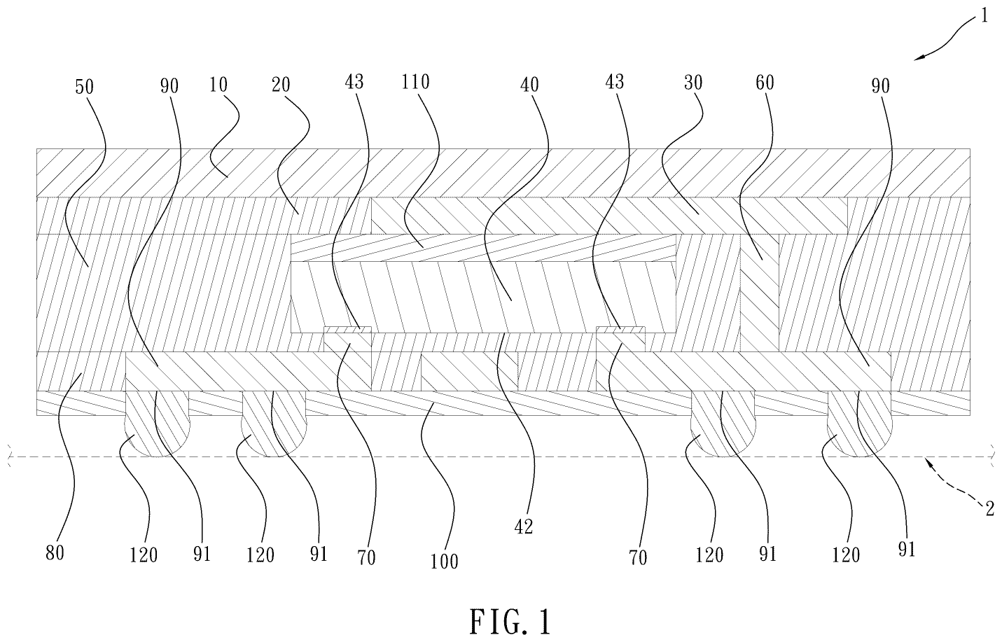

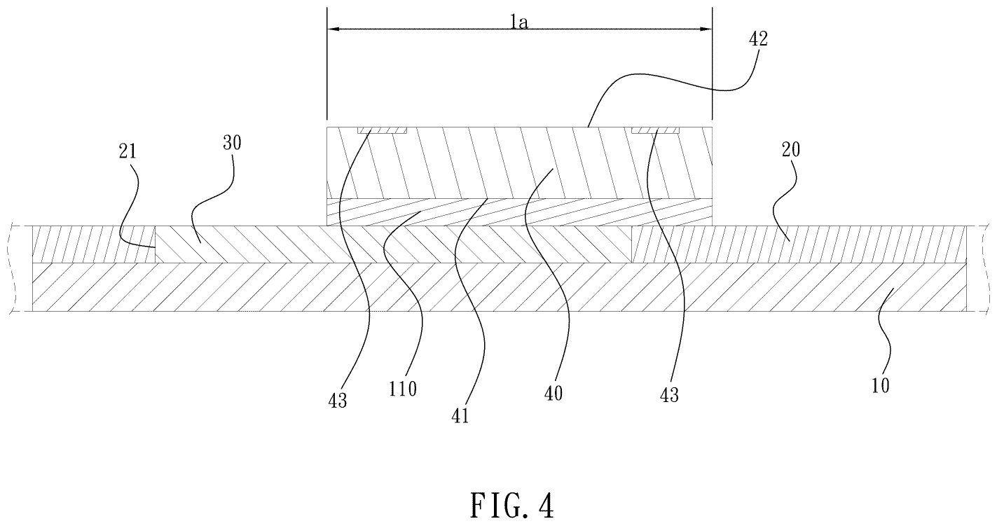

The die 40 is cut from a wafer and provided with a first surface 41 and a second surface 42 opposite to the first surface 41. The first surface 41 of the die 40 is fixed on the first dielectric layer 20 and the antenna 30 while the second surface 42 of the die 40 is provided with a plurality of die pads 43. A range perpendicular to the second surface 42 of the die 40 is defined as a chip area la, as shown in FIG. 4. In FIG. 1, there are two die pads 43 on the die 40 but the number of the die pads 43 is not limited.

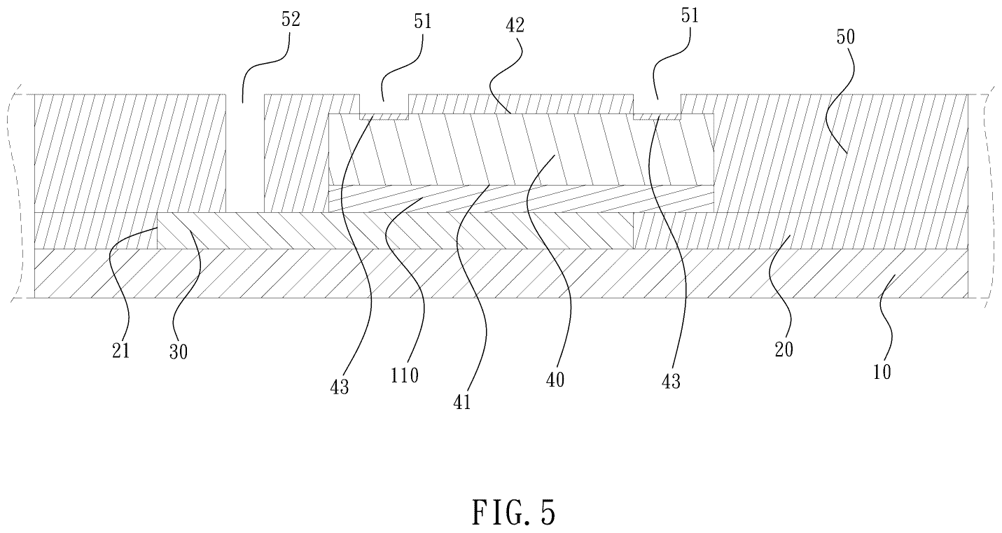

Refer to FIG. 5, the second dielectric layer 50 is disposed over the first dielectric layer 20, the antenna 30, and the second surface 42 of the die 40. The second dielectric layer 50 is provided with a plurality of second slots 51 extending horizontally and at least one insertion hole 52 penetrating the second dielectric layer 50. The respective die pads 43 of the die 40 are exposed through the respective second slots 51 and the antenna 30 is exposed through the corresponding insertion hole 52.

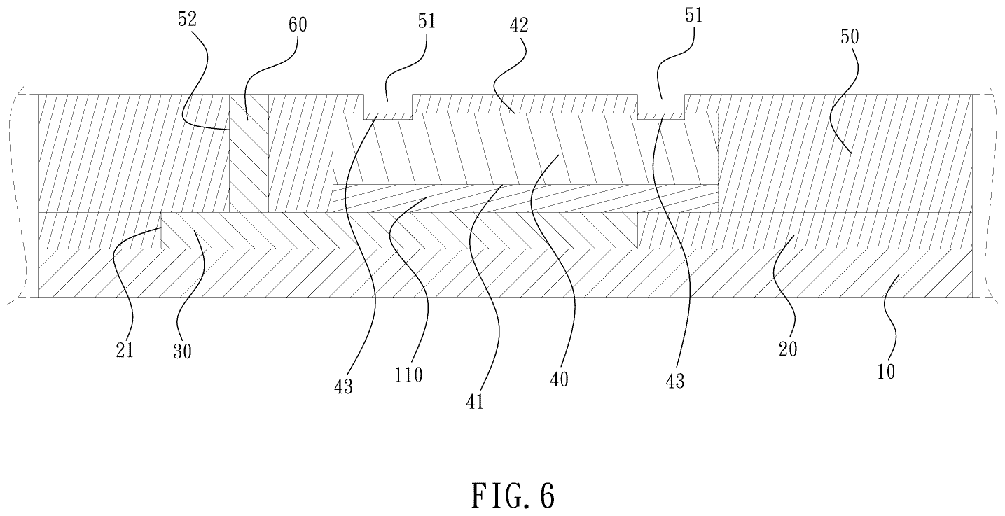

The conductive pillar 60 is formed in the insertion hole 52 and electrically connected with the antenna 30, as shown in FIG. 6.

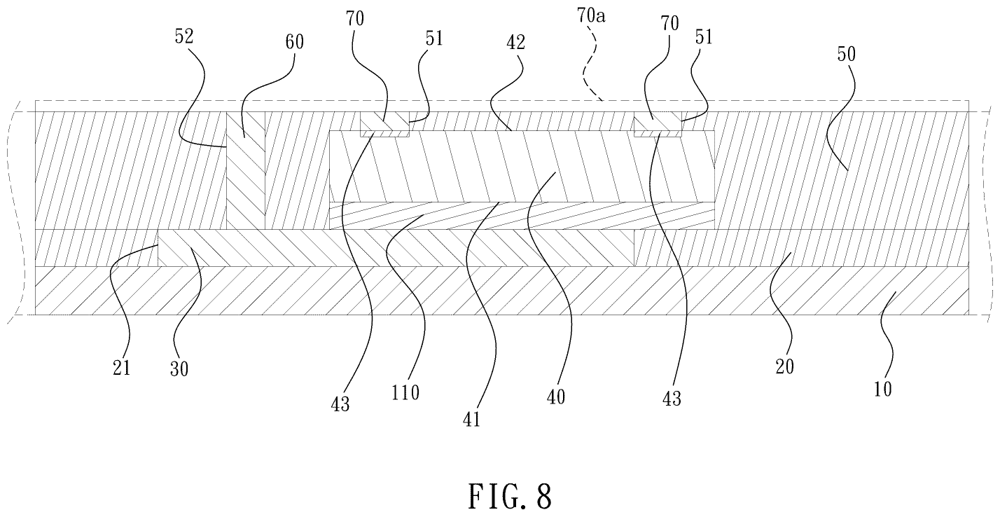

The respective first conductive circuits 70 are formed by a metal paste 70a filled in the respective second slots 51 and electrically connected with the die pads 43 of the die 40, as shown in FIG. 8.

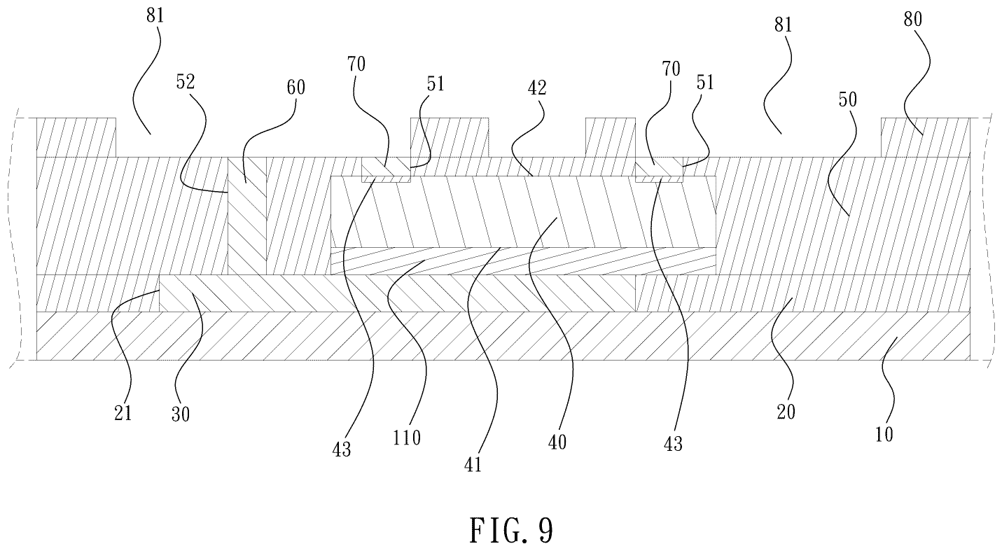

The third dielectric layer 80 is arranged over the second dielectric layer 50 and provided with a plurality of third slots 81 extending in a horizontal direction. The respective third slots 81 are communicating with the respective second slots 51, as shown in FIG. 9.

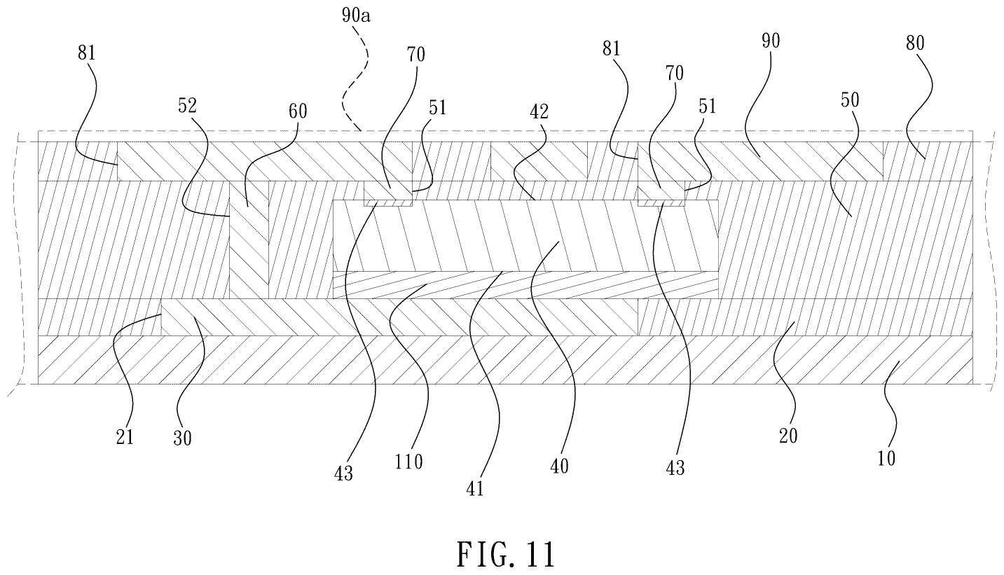

The respective second conductive circuits 90 are formed by a metal paste 90a filled in the respective third slots 81 and electrically connected with the respective first conductive circuits 70 and the conductive pillar 60, as shown in FIG. 11.

Refer to FIG. 12, the outer protective layer 100 is mounted over the third dielectric layer 80 and provided with a plurality of openings 101. At least one of the openings 101 is located around the chip area la on the second surface 42 of the die 40. The respective second conductive circuits 90 are exposed through the respective openings 101 to form a bonding pad 91 in each of the openings 101. In FIG. 12, the outer protective layer 100 includes four openings 101 and this is only an example for explanation.

The die 40 is electrically connected to the antenna 30 through the first conductive circuits 70 and the conductive pillar 60 in turn for processing reception and transmission of radiation or electromagnetic signals from the antenna 30, as shown in FIG. 12.

The die 40 is electrically connected to the outside through the die pads 43, the first conductive circuits 70, the second conductive circuits 90, and the bonding pads 91 located around the chip area 1a on the second surface 42 of the die 40 in turn. Thereby the FOWLP unit 1 is formed, as shown in FIG. 12.

A method of manufacturing the FOWLP unit 1 includes the following steps.

Step S1: providing a substrate 10, as shown in FIG. 2.

Step S2: disposing a first dielectric layer 20 on the substrate 10 and forming a plurality of first slots on the first dielectric layer 20, as shown in FIG. 2.

Step S3: forming an antenna 30 in each of the first slots 21, as shown in FIG. 2.

Step S4: arranging a plurality of dies 40 cut from at least one wafer at the first dielectric layer 20 and the antenna 30 with an interval between the two adjacent dies 40, as shown in FIG. 4. The die 40 is provided with a first surface 41 and a second surface 42 opposite to the first surface 41. The first surface 41 of the die 40 is fixed on the first dielectric layer 20 and the antenna 30 while the second surface 42 of the die 40 is provided with a plurality of die pads 43. A range perpendicular to the second surface 42 of the die 40 is defined as a chip area 1a.

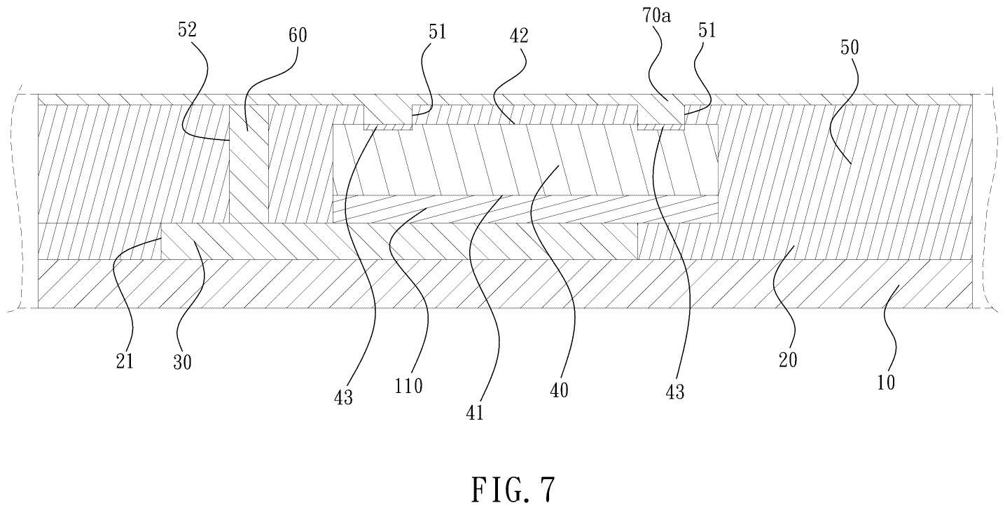

Step S5: producing a plurality of first conductive circuits 70 on the second surface 42 of the die 40 by filling a metal paste into slots and grinding the metal paste. First paving a second dielectric layer 50 over the first dielectric layer 20, the antenna 30, and the die 40. Then forming a plurality of second slots 51 extending horizontally and a plurality of insertion hole 52 on the second dielectric layer 50 and allowing the die pads 43 of the die 40 and the respective antennas 30 respectively to expose through the second slots 51 and the insertion holes 52, as shown in FIG. 5. After forming a conductive pillar 60 (as shown in FIG. 6) in each of the insertion holes 52, filling a metal paste 70a into the respective second slots 51 and allowing a level of the metal paste 70a to be higher than a surface of the second dielectric layer 50, as shown in FIG. 7. Lastly, grinding the metal paste 70a with the level higher than the surface of the second dielectric layer 50 to make a surface of the metal paste 70a flush with the surface of the second dielectric layer 50 and form a plurality of the first conductive circuits 70, as shown in FIG. 8.

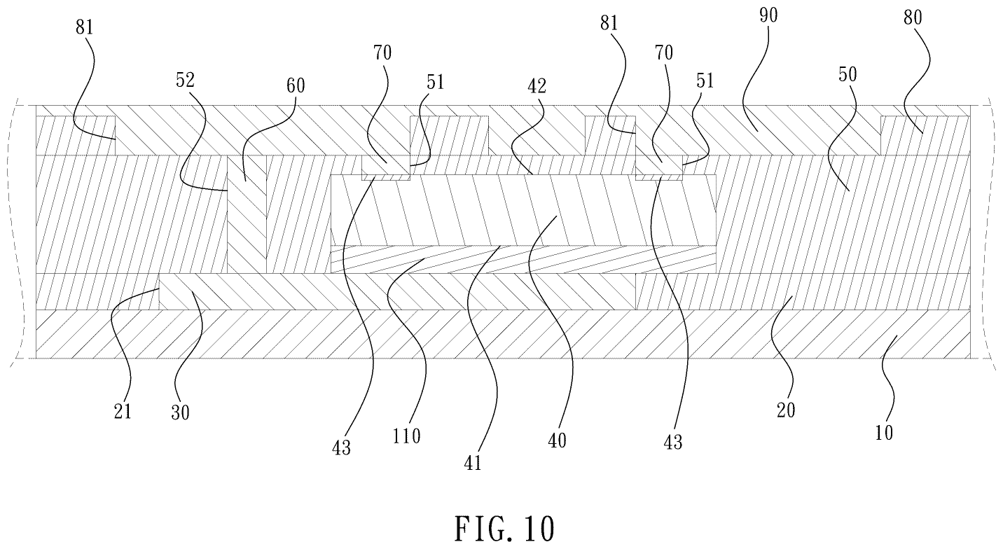

Step S6: producing a plurality of second conductive circuits 90 on the second dielectric layer 50 and the first conductive circuits 70 by filling a metal paste into slots and grinding the metal paste. First paving a third dielectric layer 80 over the second dielectric layer 50 and the first conductive circuits 70. Then forming a plurality of third slots 81 extending in a horizontal direction on the third dielectric layer 80 and allowing the first conductive circuits 70 to expose through the third slots 81, as shown in FIG. 9. Next filling a metal paste 90a into the respective third slots 81 and allowing a level of the metal paste 90a to be higher than a surface of the third dielectric layer 80, as shown in FIG. 10. Lastly, grinding the metal paste 90a with the level higher than the surface of the third dielectric layer 80 to make a surface of the metal paste 90a flush with the surface of the third dielectric layer 80 and form a plurality of the second conductive circuits 90, as shown in FIG. 11.

Step S7: covering the third dielectric layer 80 with an outer protective layer 100, as shown in FIG. 12.

Step S8: forming a plurality of openings 101 on the outer protective layer 100 and allowing at least one of the openings 101 to be located around the chip area la on the second surface 42 of the die 40 so that the respective second conductive circuits 90 are exposed through the respective openings 101 to form a bonding pad 91 in each of the openings 101, as shown in FIG. 12.

Step S9: performing cutting to form a plurality of the FOWLP units 1, as shown in FIG. 12. There is only one FOWLP unit 1 in FIG. 12 and this is only an example for explanation, not intended to limit the present invention.

Refer to FIG. 1, the substrate 10 includes silicon (Si) substrate, glass substrate, and ceramic substrate, but not limited.

Refer to FIG. 8 and FIG. 11, the metal pastes 70a, 90a which form the first conductive circuits 70 and the second conductive circuits 90 include silver paste, nano-scale silver paste, copper paste, and nano-scale copper paste. The nano-scale silver paste has features of low cost, high conductivity, and low-temperature sintering. The nano-scale silver paste is a material available now so that no more detailed description is provided.

Refer to FIG. 4, the first surface 41 of the die 40 is arranged at the first dielectric layer 20 and the antenna 30 by a die attach film (DAF) 110.

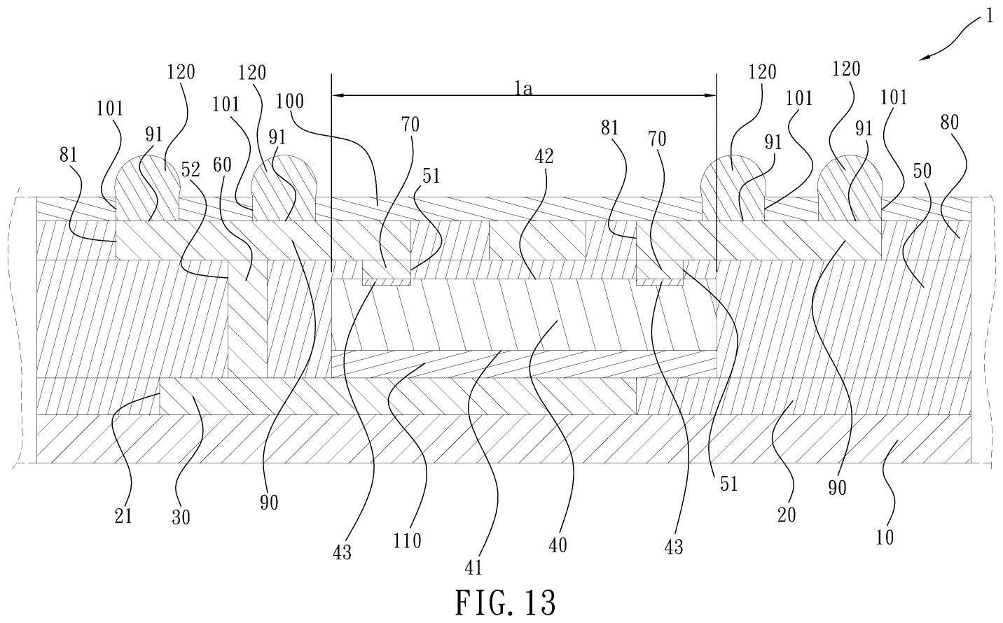

Refer to FIG. 13, each of the openings 101 is provided with a solder ball 120 which is electrically connected with the bonding pad 91 inside the opening 101. Refer to FIG. 1, the FOWLP unit 1 is electrically connected and mounted to a printed circuit board (PCB) 2 by the solder balls 90.

Compared with the FOWLP unit available now, the present FOWLP unit 1 has the following advantages.
(1) The steps S5 and S6 of the present method of manufacturing the FOWLP unit 1 are considered as key steps in production of RDL of the FOWLP unit 1. The steps S5 and S6 are precise and easily-implemented steps. Thus the manufacturing process is simplified so that a more compact design is achieved under condition that conductive circuits in the RDL make a plurality of die pads on dies have electrical extension in the XY plane and interconnections. This especially helps in reduction of the thickness of the FOWLP unit 1. Thus not only production cost is reduced, use efficiency and reliability of the FOWLP unit 1 are improved significantly.
(2) The plurality of the first conductive circuits 70 and the second conductive circuits 90 of the present invention are formed by filling metal paste into the slots first and then grinding the metal paste. Thus the problems of the FOWLP technology available now generated during manufacturing of the respective conductive circuits including higher manufacturing cost and less environmental benefit can be solved effectively by the present invention.
(3) The respective antennas 30 of the present invention are embedded inside the FOWLP unit 1 directly, instead of being added after packaging. This helps simplification of the manufacturing process and reduction of the thickness of the packaging unit. Thereby light weight and small size requirements of the electronic devices are met.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A fan-out wafer level packaging (FOWLP) unit comprising:
a substrate;
a first dielectric layer arranged at the substrate and provided with at least one first slot extending in a horizontal direction;
at least one antenna mounted in the first slot;
at least one die cut from a wafer and having a first surface and a second surface opposite to each other; the first surface of the die fixed on the first dielectric layer and the antenna while the second surface of the die provided with a plurality of die pads; a range perpendicular to the second surface of the die being defined as a chip area;
a second dielectric layer disposed over the first dielectric layer, the antenna, and the second surface of the die; the second dielectric layer provided with a plurality of second slots extending in a horizontal direction and at least one insertion hole penetrating the second dielectric layer; wherein the die pads of the die are exposed through the respective second slots; wherein the antenna is exposed through the insertion hole;
at least one conductive pillar formed in the insertion hole and electrically connected with the antenna;
a plurality of first conductive circuits formed by a metal paste filled in the second slots and electrically connected with the die pads of the die correspondingly;
a third dielectric layer arranged over the second dielectric layer and provided with a plurality of third slots which is extending in a horizontal direction and communicating with the second slots;
a plurality of second conductive circuits formed by a metal paste filled in the third slots and electrically connected with both the first conductive circuits and the conductive pillar; and
an outer protective layer mounted over the third dielectric layer and provided with a plurality of openings; wherein at least one of the openings is located around the chip area on the second surface of the die; wherein the second conductive circuits are exposed through the openings to form a bonding pad in each of the openings;
wherein the die is electrically connected to the antenna through the first conductive circuits and the conductive pillar in turn;
wherein the die is electrically connected to the outside through the die pads, the first conductive circuits, the second conductive circuits, and the bonding pads located around the chip area on the second surface of the die in turn; thereby the FOWLP unit is formed;
wherein a method of manufacturing the FOWLP unit comprising the steps of:
Step S1: providing a substrate;
Step S2: disposing a first dielectric layer on the substrate and forming a plurality of first slots on the first dielectric layer;
Step S3: forming an antenna in each of the first slots; 6
Step S4: arranging a plurality of dies cut from at least one wafer at the first dielectric layer and the antenna with an interval between the two adjacent dies; wherein the die is provided with a first surface and a second surface opposite to the first surface; the first surface of the die is fixed on the first dielectric layer and the antenna; the second surface of the die is provided with a plurality of die pads; a range perpendicular to the second surface of the die is defined as a chip area;
Step S5: producing a plurality of first conductive circuits on the second surface of the die by filling a metal paste into slots and grinding the metal paste; first paving a second dielectric layer over the first dielectric layer, the antenna, and the die; then forming a plurality of second slots extending horizontally and a plurality of insertion holes on the second dielectric layer and allowing the die pads of the die and the antennas respectively to expose through the second slots and the insertion holes; next forming a conductive pillar in each of the insertion holes, filling a metal paste into the second slots, and allowing a level of the metal paste to be higher than a surface of the second dielectric layer; lastly, grinding the metal paste with the level higher than the surface of the second dielectric layer to make a surface of the metal paste flush with the surface of the second dielectric layer and form a plurality of the first conductive circuits;
Step S6: producing a plurality of second conductive circuits on the second dielectric layer and the first conductive circuits by filling a metal paste into slots and grinding the metal paste; first paving a third dielectric layer over the second dielectric layer and the first conductive circuits; then forming a plurality of third slots extending in a horizontal direction on the third dielectric layer and allowing the first conductive circuits to expose through the third slots; later filling a metal paste into the third slots and allowing a level of the metal paste to be higher than a surface of the third dielectric layer; lastly, grinding the metal paste with the level higher than the surface of the third dielectric layer to make a surface of the metal paste flush with the surface of the third dielectric layer and form a plurality of the second conductive circuits;
Step S7: covering the third dielectric layer with an outer protective layer;
Step S8: forming a plurality of openings on the outer protective layer and allowing at least one of the openings to be located around the chip area on the second surface of the die so that the second conductive circuits are exposed through the openings correspondingly to form a bonding pad in each of the openings; and
Step S9: performing cutting to form a plurality of the FOWLP units.

2. The FOWLP unit as claimed in claim 1, wherein the substrate includes silicon (Si) substrate, glass substrate, and ceramic substrate.

3. The FOWLP unit as claimed in claim 1, wherein the metal paste which forms the first conductive circuits includes silver paste, nano-scale silver paste, copper paste, and nano-scale copper paste.

4. The FOWLP unit as claimed in claim 1, wherein the metal paste which forms the second conductive circuits includes silver paste, nano-scale silver paste, copper paste, and nano-scale copper paste.

5. The FOWLP unit as claimed in claim 1, wherein the first surface of the die is arranged at the first dielectric layer and the antenna by a die attach film (DAF).

6. The FOWLP unit as claimed in claim 1, wherein each of the openings is provided with a solder ball which is electrically connected with the bonding pad inside the opening.

7. The FOWLP unit as claimed in claim 6, wherein the FOWLP unit is electrically connected and mounted to a printed circuit board (PCB) by the solder balls.
